(19) United States
(12) Patent Application Publication
(10) Pub. No.: US 2013/0012033 A1
(43) Pub. Date: Jan. 10, 2013

(54) SILICON OXIDE FILM FORMING METHOD AND PLASMA OXIDATION APPARATUS

(75) Inventors: Yoshiro Kabe, Nirasaki City (JP); Shuichiro Otao, Amagasaki City (JP); Yoshihiro Sato, Nirasaki City (JP)

(73) Assignee: Tokyo Electron Limited, Tokyo (JP)

(21) Appl. No.: 13/636,030

(22) PCT Filed: Mar. 9, 2011
(86) PCT No.: PCT/JP11/55482

§ 371 Date: Sep. 19, 2012

(30) Foreign Application Priority Data
Mar. 19, 2010 (JP) 2010-064080

(51) Int. Cl. H01L 21/316; C23C 16/511

(52) U.S. Cl. 438/771; 118/723 AN; 257/E21.283

(57) ABSTRACT

A silicon oxide film forming method includes forming a silicon oxide film by allowing a plasma of a processing gas to react on a silicon exposed on a surface of a target object to be processed in a processing chamber of a plasma processing apparatus. The processing gas includes an ozone-containing gas having a volume ratio of O₃ to a total volume of O₂ and O₃, ranging 50% or more.

### FIELD OF THE INVENTION

The present invention relates to a silicon oxide film forming method that can be applied to, e.g., a process for manufacturing various semiconductor devices, and a plasma processing apparatus.

### BACKGROUND OF THE INVENTION

In a manufacturing process of various semiconductor devices, a silicon oxide film is formed by oxidizing a silicon substrate. As for a method for forming a silicon oxide film on a silicon surface, there are known a thermal oxidation process using an oxidation furnace or a RTP (Rapid Thermal Process) apparatus and a plasma oxidation process using a plasma processing apparatus.

For example, in a wet oxidation process using an oxidation furnace which is one of the thermal oxidation processes, a silicon substrate is heated to a temperature of about 800° C. or above and exposed to an oxidation atmosphere by using water vapor generated by a WVG (Water Vapor Generator), so that a silicon surface is oxidized to thereby form a silicon oxide film. The thermal oxidation is considered as a method capable of forming a good-thickness silicon oxide film. Since, however, the thermal oxidation needs to be performed at a high temperature of about 800° C. or above, a thermal budget is increased and the silicon substrate is distorted due to thermal stress.

Meanwhile, plasma oxidation is generally performed by using oxygen gas. For example, International Patent Application Publication No. WO 2004/008519 suggests a method for performing plasma oxidation by allowing a microwave-excited plasma to react on a silicon surface, the microwave-excited plasma being generated in a processing chamber whose pressure is about 133.3 Pa by using a processing gas containing argon gas and oxygen gas at an oxygen flow rate ratio of about 1%. In the method described in International Patent Application Publication WO 2004/008519, the plasma oxidation is performed at a relatively low processing temperature of about 400° C., so that it is possible to avoid the problems such as the increase of the thermal budget and the distortion of the substrate in the thermal oxidation.

Further, there is suggested a technique for performing plasma oxidation by using ozone gas instead of oxygen gas. For example, in Japanese Patent Application Publication No. 10-500386 suggests a method for forming a thin silicon dioxide film by allowing a silicon-containing solid to react on a flow of an ozone decomposition product at about 300° C. or below, the ozone decomposition product being generated by decomposing ozone at a pressure of about 1 Torr inside a microwave discharge opening.

In a process for oxidizing a silicon wafer by using an ECR (Electron Cyclone Resonance) plasma, a higher oxidation rate is obtained in a first case that ozone gas is used at a processing pressure of about 1.3 Pa compared to in a second case that an oxygen gas is used at a processing pressure of about 1.3 Pa [Matsumura Yukiteru, T. IEE Japan, Vol. 111-A, Nov. 12, 1991]. Referring to this document, in both the cases, a silicon oxide film formed at an extremely low processing pressure of about 1 Pa by using the ECR plasma has substantially the same interface state density.

Generally, it is considered that a silicon oxide film has a poor film quality when being formed by plasma oxidation compared to when being formed by thermal oxidation, since it is damaged by the plasma (ions or the like). Therefore, the thermal oxidation is currently widely used. However, if a silicon oxide film having a good quality same as that of a thermal oxide film can be formed by plasma oxidation, it is possible to solve problems caused by high-temperature thermal oxidation. Therefore, there is required a method capable of forming a silicon oxide film having an improved film quality by plasma oxidation.

### SUMMARY OF THE INVENTION

In view of the above, the present invention provides a plasma oxidation method capable of forming a silicon oxide film having a film quality higher than or equal to that of a thermal oxide film.

In accordance with an aspect of the present invention, there is provided a silicon oxide film forming method including forming a silicon oxide film by allowing a plasma of a processing gas to react on a silicon exposed on a surface of a target object to be processed in a processing chamber of a plasma processing apparatus, the processing gas including an ozone-containing gas having a volume ratio of O₃ to a total volume of O₂ and O₃, ranging 50% or more.

In the silicon oxide film forming method, a pressure in the processing chamber may range from about 1.3 Pa to about 1333 Pa.

In the silicon oxide film forming method, an oxidation process may be performed while a high frequency power is supplied to a mounting table for mounting thereon the target object in the processing chamber. In this case, it is preferable to supply the high frequency power of a magnitude within a range from about 0.2 W/cm² to 1.3 W/cm² per an area of the target object.

In the silicon oxide film forming method, a processing temperature may correspond to a temperature of the target object and ranges from about 20° C. to 600° C.

In the silicon oxide film forming method, the plasma may correspond to a microwave-excited plasma formed by using the processing gas and a microwave introduced into the processing chamber by a planar antenna having a plurality of slots. In this case, a power density of the microwave preferably ranges from about 0.255 W/cm² to 2.55 W/cm² per unit area of the target object.

In accordance with another aspect of the present invention, there is provided a plasma oxidation apparatus including a processing chamber having an opening formed at an upper portion thereof, for processing a target object to be processed by using a plasma; a dielectric member for covering the opening of the processing chamber, an antenna provided outside the dielectric member, for introducing an electromagnetic wave into the processing chamber; a gas inlet for introducing a processing gas including an ozone-containing gas into the processing chamber; a gas exhaust port for vacuum-evacuating the inside of the processing chamber; a mounting table for mounting the target object thereon in the processing chamber; and a control unit configured to form a silicon oxide film by supplying into the processing chamber a processing gas containing an ozone-containing gas having a volume ratio of O₃ to a total volume of O₂ and O₃, ranging 50% or more, while introducing an electromagnetic wave into the processing chamber by the antenna, and generating a plasma of the processing gas and allowing the plasma to react on a silicon exposed on the surface of the target object.

The plasma oxidation apparatus may further include a gas supply line, of which inner surface is subjected to a passivation process, for supplying the ozone-containing gas into the processing chamber, the gas supply line having one end connected to the gas inlet and the other end connected to an ozone-containing gas supply source. In this case, the gas inlet may include a gas channel having a gas opening through which a gas is injected into a processing space in the processing chamber, and a passivation process is performed on a part or an entire part of the gas channel and an inner wall surface of the processing chamber around the gas opening.

The plasma oxidation apparatus may further include a high frequency power supply for supplying a high frequency power ranging from about 0.2 W/cm² to 1.3 W/cm² per unit area of the target object to the mounting table.

In accordance with a silicon oxide film forming method of the present invention, it is possible to form a silicon oxide film having a film quality higher than or equal to that of a thermal oxide film by forming a silicon oxide film by allowing a plasma of a processing gas including ozone-containing gas with a volume ratio of O₃ to a total volume of O₂ and O₃, ranging 50% or more.

### BRIEF DESCRIPTION OF THE DRAWINGS

FIG. 1 is a schematic cross sectional view showing an example of a plasma processing apparatus which is suitable for implementation of a silicon oxide film forming method in accordance with an embodiment of the present invention;

FIG. 2 is a configuration example showing a gas supply unit;

FIG. 3 is an enlarged cross sectional view showing a gas inlet in a processing chamber;

FIG. 4 shows a structure of a planar antenna;

FIG. 5 explains a configuration of a control unit;

FIG. 6 is a graph showing a difference (vertical axis) between binding energies of a silicon oxide film and a silicon which can be obtained from an XPS spectrum of an oxide film and a difference (horizontal axis) between binding energies of oxygen and a silicon oxide film in a test 1;

FIG. 7 is a graph showing a processing pressure dependency of a film thickness of a silicon oxide film in a test 2;

FIG. 8A is a graph showing a relationship between a film thickness (vertical axis) of a silicon oxide film and a volume flow rate ratio (horizontal axis) of an ozone-containing gas or an oxygen gas to all processing gases in a test 3;

FIG. 8B explains a relationship between a volume ratio of “O₃/(O₂+O₃)” and a radical flux of “O(¹D₂)”;

FIG. 9 is a graph showing a relationship between a power density (horizontal axis) of a high frequency power supplied to a mounting table and an intra-wafer surface uniformity (vertical axis) of a silicon oxide film in a test 4; and

FIG. 10 is a graph showing a relationship between a high frequency power density (horizontal axis) and an oxide film thickness (vertical axis) in the test 4.

### DETAILED DESCRIPTION OF THE EMBODIMENTS

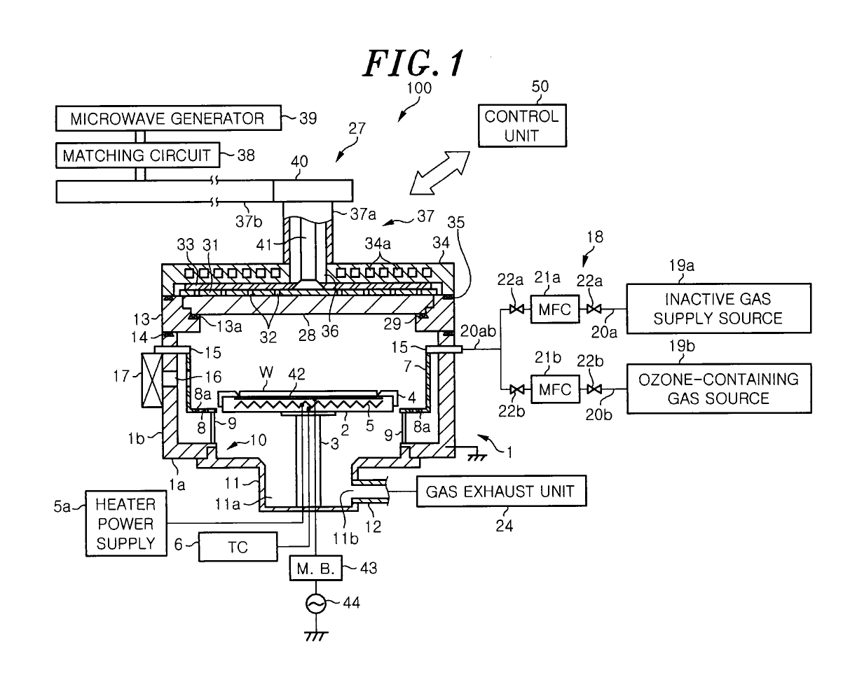

Hereinafter, an embodiment of the present invention will be described with reference to the accompanying drawings. FIG. 1 is a schematic cross sectional view showing an example of a plasma processing apparatus 100 which is usable for a silicon oxide film forming method of the present invention.

The plasma processing apparatus 100 is configured as an RLSA (Radial Line Slot Antenna) microwave plasma processing apparatus capable of obtaining a microwave-excited plasma of a high density and a low electron temperature by introducing a microwave into a processing chamber through a planar antenna, particularly, an RLSA, having a plurality of slot-shaped holes and generating a plasma in the processing chamber. In the plasma processing apparatus 100, a process can be performed by using a plasma of a plasma density in a range from, e.g., about 1×10¹⁰/cm³ to 5×10¹²/cm³ and a low electron temperature in a range from, e.g., about 0.7 eV to 2 eV. Accordingly, the plasma processing apparatus 100 can be suitably used for the purpose of forming a silicon oxide film (e.g., SiO₂ film) in a manufacturing process of various semiconductor devices.

The plasma processing apparatus 100 includes, as main elements, an airtight processing chamber 1; a gas inlet 15 connected to a gas supply unit 18, for introducing a gas into the processing chamber 1; a gas exhaust port 11b connected to a gas exhaust unit 24, for vacuum-evacuating the processing chamber 1; a microwave introducing unit 27, provided at an upper portion of the processing chamber 1, for introducing a microwave into the processing chamber 1; and a control unit 50 for controlling various components of the plasma processing apparatus 100. Further, the gas supply unit 18 may be included in the plasma processing apparatus 100. Alternatively, the gas supply unit 18 may be connected as an external unit to the plasma processing apparatus 100.

The processing chamber 1 is grounded and formed in an approximately cylindrical shape. The processing chamber 1 has a bottom wall 1a and a sidewall 1b made of aluminum or the like. Moreover, the processing chamber 1 may be formed in a square tubular shape.

A mounting table 2 for horizontally supporting a silicon wafer (wafer W) as a target object to be processed is provided in the processing chamber 1. The mounting table 2 is formed of a material, e.g., ceramic such as AlN, of a high thermal conductivity. The mounting table 2 is supported by a cylindrical support member 3 extending upwardly from a central bottom portion of a gas exhaust chamber 11. The support member 3 is made of, e.g., ceramic such as AlN or the like.

Further, a cover ring 4 is provided in the mounting table 2 to cover an outer peripheral portion of the mounting table 2 and guide the wafer W. Although the cover ring 4 may be formed in a ring shape or may be formed on an entire surface of the mounting table 2, the cover ring 4 is preferably configured to cover the entire surface of the mounting table 2. The presence of the cover ring 4 makes it possible to prevent the intrusion of impurities to the wafer W. The cover ring 4 is made of, e.g., quartz, single crystalline silicon, polysilicon, amorphous silicon, SiN or the like. Among them, quartz is most preferably used. The material of the cover ring 4 preferably has a high purity having low concentration of impurities, such as an alkali metal, a metal or the like.

A resistance heater 5 as a temperature adjusting unit is embedded in the mounting table 2. The heater 5 is powered from a heater power supply 5a to heat the mounting table 2, thereby uniformly heating the wafer W as the target object.

A thermocouple (TC) 6 is also provided in the mounting table 2. The temperature of the mounting table 2 is measured by the thermocouple 6, so that the heating temperature of the wafer W can be controlled in a range from a room temperature to 900° C.

Further, wafer support pins (not shown) for supporting and lifting the wafer W are provided in the mounting table 2.

Each of the wafer support pins is provided to protrude from and retreat into the top surface of the mounting table 2.

A cylindrical liner 7 made of quartz is disposed on an inner periphery of the processing chamber 1. In addition, an annular baffle plate 8 made of quartz is disposed on an outer peripheral side of the mounting table 2 to uniformly evacuate the processing chamber 1. The baffle plate 8 has a plurality of gas exhaust holes 8a and is supported by a plurality of support columns 9.

A circular opening 10 is formed in an approximately central portion of the bottom wall la of the processing chamber 1. The gas exhaust chamber 11 is provided in the bottom wall 1a to protrude downward and communicate with the opening 10. The gas exhaust port 11b is provided at the gas exhaust chamber 11, and a gas exhaust line 12 is connected to the gas exhaust port 11b. The gas exhaust chamber 11 is connected to the gas exhaust unit 24 serving as a gas exhaust device through the gas exhaust line 12.

An annular plate 13 is provided at an upper portion of the processing chamber 1. An inner peripheral portion of the plate 13 protrudes inwardly (toward the inner space of the processing chamber) and thus forms an annular support portion 13a. The space between the plate 13 and the processing chamber 1 is airtightly sealed by a sealing member 14.

The gas inlet 15 has an annual shape and is disposed at the sidewall lb of the processing chamber 1. The gas inlet 15 is connected to the gas supply unit 18 for supplying a processing gas. The gas inlet 15 may be formed in a nozzle shape or a shower shape. The structure of the gas inlet 15 will be described later.

Provided in the sidewall lb of the processing chamber 1 are a loading/unloading port 16 through which the wafer W is loaded/unloaded between the plasma processing apparatus 100 and a transfer chamber (not shown) adjacent to the plasma processing apparatus 100, and a gate valve 17 for opening and closing the loading/unloading port 16.

The gas supply unit 18 includes, e.g., an inactive gas supply source 19a and an ozone-containing gas supply source 19b. Further, the gas supply unit 18 may include, e.g., a purge gas supply source used for changing the atmosphere in the processing chamber 1, as well as the above-described gas supply sources.

The inactive gas is used as a plasma excitation gas for generating a stable plasma. An example of the inactive gas may include a rare gas or the like. An example of the rare gas may include, e.g., Ar gas, Kr gas, Xe gas, He gas or the like. Among them, it is preferable to use Ar gas capable of ensuring economical efficiency and stably generating a plasma thereby realizing uniform plasma oxidation.

The ozone-containing gas is decomposed into oxygen radicals or oxygen ions which are contained in a plasma and serves as oxygen source gas for oxidizing a silicon by reaction with the silicon. Unless otherwise particularly specified, “ozone-containing gas” refers to a gas containing O₂ and O₃ in this specification. A high concentration ozone-containing gas having a volume ratio of O₃ to a total volume of O₂ and O₃ contained in the gas, ranging 50% or more, or preferably from 60 to 80%, may be employed as for the ozone-containing gas. By using such an ozone-containing gas containing O₃ of high concentration, it is possible to improve a film quality of a silicon oxide film.

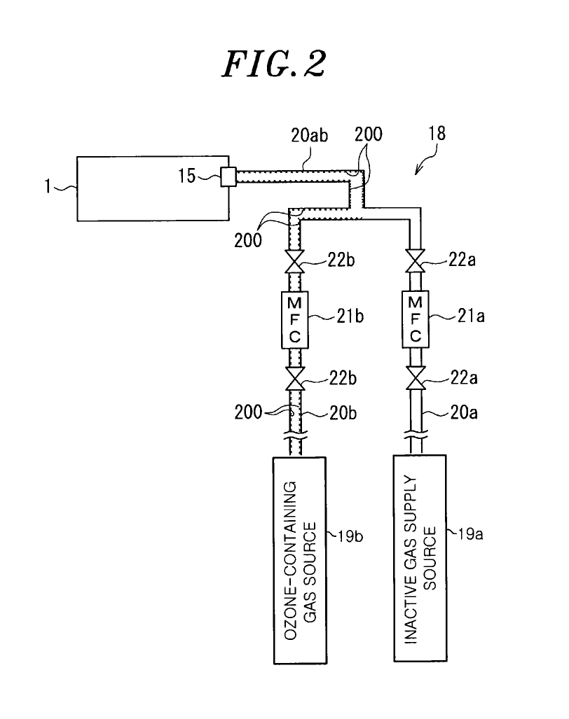

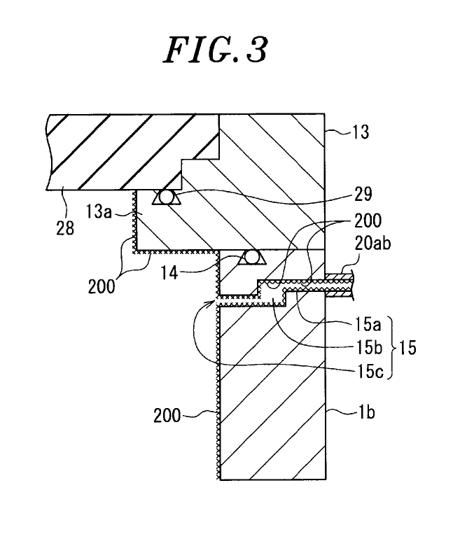

FIG. 2 is an enlarged view showing a line configuration in the gas supply unit 18. FIG. 3 is an enlarged view showing a configuration of the gas inlet 15 in the processing chamber 1. The inactive gas supplied from an inactive gas supply source 19a reaches the gas inlet 15 through gas lines 20a and 20ab serving as gas supply lines, and then is introduced into the processing chamber 1 from the gas inlet 15. Further, the ozone-containing gas supplied from the ozone-containing gas supply source 19b reaches the gas inlet 15 through gas lines 20b and 20ab serving as gas supply lines, and then is introduced into the processing chamber 1 from the gas inlet 15.

The gas lines 20a and 20b are merged in their middle portions to form the single gas line 20ab. The gas lines 20a and 20b are connected to the respective gas supply sources and are provided with mass flow controllers 21a and 21b and opening/closing valves 22a and 22b disposed at an upstream side and a downstream side thereof. By such a configuration of the gas supply unit 18, it is possible to switch the supplied gases and control flow rates of the supplied gases.

The ozone-containing gas supply source 19b may be, e.g., an ozone-containing gas bomb for storing an ozone-containing gas containing O₃ of high concentration, or may be an ozonizer for generating an ozone-containing gas containing O₃ of high concentration. Alternatively, an O₂ gas supply source and an O₃ gas supply source may be provided to separately provide corresponding gases.

The inner surfaces of the gas lines 20b and 20ab extending from the ozone-containing gas supply source 19b to the gas inlet 15 are subjected to a passivation process for preventing an abnormal reaction and a self-decomposition (deactivation) of ozone when an ozone-containing gas containing O₃ of high concentration circulates therethrough. The passivation process can be performed by exposing inner walls of the gas lines 20b and 20ab made of, e.g., stainless steel or the like, to the ozone-containing gas containing O₃ of high concentration. Accordingly, Fe elements and Cr elements of stainless steel are oxidized, and a passivation film 200 of a metal oxide is formed on the inner surfaces of the gas lines 20b and 20ab.

Specifically, the passivation process is preferably performed by reacting, on a metal surface, the ozone-containing gas having a volume ratio of O₃ to a total volume of O₂ and O₃, ranging from 15 to 50 vol %, at a temperature in a range from, e.g., about 60° C. to 150° C. In that case, the formation of the passivation film 200 can be facilitated by allowing the ozone-containing gas to contain moisture of about 2 vol % or less.

In the plasma processing apparatus 100 of the present embodiment, a passivation process is performed on the gas inlet 15 formed at the processing chamber 1 in order to introduce an ozone-containing gas containing O₃ of high concentration into the processing chamber 1. The gas inlet 15 of the processing chamber 1 has a gas channel connected to the gas line 20ab. As in the gas lines 20b and 20ab, a passivation process is performed on some parts or an entire part of the gas channel, so that the passivation film 200 is formed thereon.

Specifically, the gas inlet 15 includes: a gas inlet line 15a formed inside the processing chamber 1; an annular common distribution line 15b, provided in a substantially horizontal direction inside the wall of the processing chamber 1, communicating with the gas inlet line 15a; and a plurality of gas openings 15c through which the common distribution line 15b communicates with a processing space in the processing chamber 1. Each of the gas openings 15c comes into contact with the processing space in the processing chamber 1, and a gas is ejected toward the processing space through the gas openings 15c. In the present embodiment, the passivation film 200 is formed on the inner surfaces of the gas inlet line 15a and the common distribution line 15b. If necessary, the gas openings 15c may be subjected to a passivation process.

In the plasma processing apparatus 100 of the present embodiment, since an ozone-containing gas containing O₃ of high concentration is used, the passivation process is performed on peripheral surfaces of the gas openings 15c that come into contact with the processing chamber 1. In other words, as shown in FIG. 3, the passivation film 200 is formed on the inner wall surface of the sidewall lb of the processing chamber 1 where the gas openings 15c are provided and the wall surface of the support portion of the plate 13.

As described above, the passivation film 200 is formed by performing the passivation process on the inner wall surfaces of the gas lines 20b and 20ab, the gas inlet line 15a and the common distribution line 15b and the peripheral wall surfaces of the gas openings 15c of the processing chamber 1. Thus, it is possible to use a high concentration ozone-containing gas that is difficult to be used in a conventional plasma processing apparatus and also possible to stably supply the ozone-containing gas into the processing chamber 1 while maintaining the high concentration of the ozone-containing gas. Further, a plasma process using a high concentration ozone-containing gas can be performed.

The gas exhaust unit 24 includes a high-speed vacuum pump, e.g., a turbo molecular pump or the like. As described above, the gas exhaust unit 24 is connected to the gas exhaust chamber 11 of the processing chamber 1 through the gas exhaust line 12. The gas in the processing chamber uniformly flows in the space 11a of the gas exhaust chamber 11 and is exhausted from the space 11a through the gas exhaust line 12 by operating the gas exhaust unit 24. Accordingly, an internal pressure of the processing chamber 1 can be rapidly reduced to, e.g., about 0.133 Pa.

Next, a configuration of the microwave introducing unit 27 will be described. The microwave introducing unit includes, as main elements, a transmitting plate 28 serving as a dielectric member; a planar antenna 31; a slow-wave member 33; a cover member 34; a waveguide 37; a matching circuit 38; and a microwave generator 39.

The transmitting plate 28, which serves to transmit a microwave, is disposed on the support portion 13a protruding inward in the plate 13. The transmitting plate 28 is made of a dielectric material, e.g., quartz or ceramic such as Al₂O₃, AlN or the like. A seal member 29 is provided to airtightly seal a gap between the transmitting plate 28 and the support portion 13a, thereby maintaining airtightness of the processing chamber 1.

The planar antenna 31 is provided on the transmitting plate 28 (outside the processing chamber 1) to face the mounting table 2. The planar antenna 31 has a disc shape. However, the planar antenna 31 may have, e.g., a rectangular plate shape without being limited to a disc shape. The planar antenna 31 is engaged with the upper end of the plate 13.

The planar antenna 31 is formed of a conductive member made of, e.g., a copper plate, an aluminum plate, a nickel plate, or a plate of an alloy thereof which is plated with gold or silver. The planar antenna 31 has a plurality of slot-shaped microwave radiation holes 32 through which the microwave is radiated. The microwave radiation holes 32 are formed in a predetermined pattern to extend through the planar antenna 31.

FIG. 4 is a top view showing a planar antenna of the plasma processing apparatus 100 shown in FIG. 1. As shown in FIG. 4, each of the microwave radiation holes 32 has, e.g., an elongated rectangular shape (slot shape). Further, generally, the adjacent microwave radiation holes 32 are arranged in a “T” shape. The microwave radiation holes 32 which are combined in groups in a specific shape (e.g., T shape) are wholly arranged in a concentric circular pattern.

A length and an arrangement interval of the microwave radiation holes 32 are determined based on the wavelength (λg) of the microwave. For example, the microwave radiation holes 32 are arranged at the interval of λg/4, λg/2, or λg. In FIG. 4, the interval between the adjacent microwave radiation holes 32 formed the concentric circular pattern is represented as Δr. The microwave radiation holes 32 may have another shape such as a circular shape, a circular arc shape or the like. Further, the microwave radiation holes 32 may be arranged in another pattern, e.g., a spiral shape, a radial shape or the like, without being limited to the concentric circular pattern.

The slow-wave member 33 having a larger dielectric constant than that of the vacuum is provided on an upper surface of the planar antenna 31. Since the microwave has a longer wavelength in the vacuum, the slow-wave member 33 functions to shorten the wavelength of the microwave to adjust a plasma. For example, quartz, polytetrafluoroethylene resin, polyimide resin or the like may be used as the material of the slow-wave member 33.

The planar antenna 31 may be in contact with or separated from the transmitting plate 28, but it is preferable that the planar antenna 31 is in contact with the transmitting plate 28. Further, the slow-wave member 33 may be in contact with or separated from the planar antenna 31, but it is preferable that the slow-wave member 33 is in contact with the planar antenna 31.

The cover member 34 is provided at the top of the processing chamber 1 to cover the planar antenna 31 and the slow-wave member 33. The cover member 34 is made of a metal material such as aluminum, stainless steel, or the like. A flat waveguide is constituted by the cover member 34 and the planar antenna 31, so that the microwave can be uniformly supplied into the processing chamber 1. A sealing member 35 is provided to seal a gap between an upper end of the plate 13 and the cover member 34. Further, the cover member 34 has a cooling water passage 34a formed therein. The cover member 34, the slow-wave member 33, the planar antenna 31 and the transmitting plate 28 may be cooled by flowing a cooling water through the cooling water passage 34a. Further, the cover member 34 is grounded.

An opening 36 is formed in a central portion of an upper wall (ceiling) of the cover member 34. The opening 36 is connected to one end of the waveguide 37. The microwave generator 39 for generating a microwave is connected to the other end of the waveguide 37 via the matching circuit 38.

The waveguide 37 includes a coaxial waveguide 37a having a circular cross section and extending upward from the opening 36 of the cover member 34; and a rectangular waveguide 37b connected to the upper end of the coaxial waveguide 37a via a mode transducer 40 and extended in a horizontal direction. The mode transducer 40 functions to convert a microwave propagating in a TE mode in the rectangular waveguide 37b into a TEM mode microwave.

An internal conductor 41 extends through the center of the coaxial waveguide 37a. A lower end of the internal conductor 41 is connected and fixed to a central portion of the planar antenna 31. With this structure, the microwaves are efficiently, uniformly and radially propagated to the flat waveguide constituted by the planar antenna 31 through the internal conductor 41 of the coaxial waveguide 37a.

By the microwave introducing unit 27 having the above configuration, the microwave generated in the microwave generator 39 is propagated to the planar antenna 31 through the waveguide 37 and then introduced into the processing chamber 1 through the microwave radiation holes (slots) 32 via the transmitting plate 28. The microwave preferably has a frequency of, e.g., 2.45 GHz, but the frequency of the microwave may be 8.35 GHz, 1.98 GHz or the like

In addition, an electrode 42 is embedded in the surface of the mounting table 2. The electrode 42 is connected to a high frequency power supply 44 for bias application via a matching box (M.B.) 43. By supplying a high frequency bias power to the electrode 42, a bias voltage can be applied to the wafer W (target object to be processed). The electrode 42 may be made of a conductive material, e.g., molybdenum, tungsten or the like. The electrode 42 is formed in, e.g., a mesh shape, a lattice shape, a spiral shape, or the like.

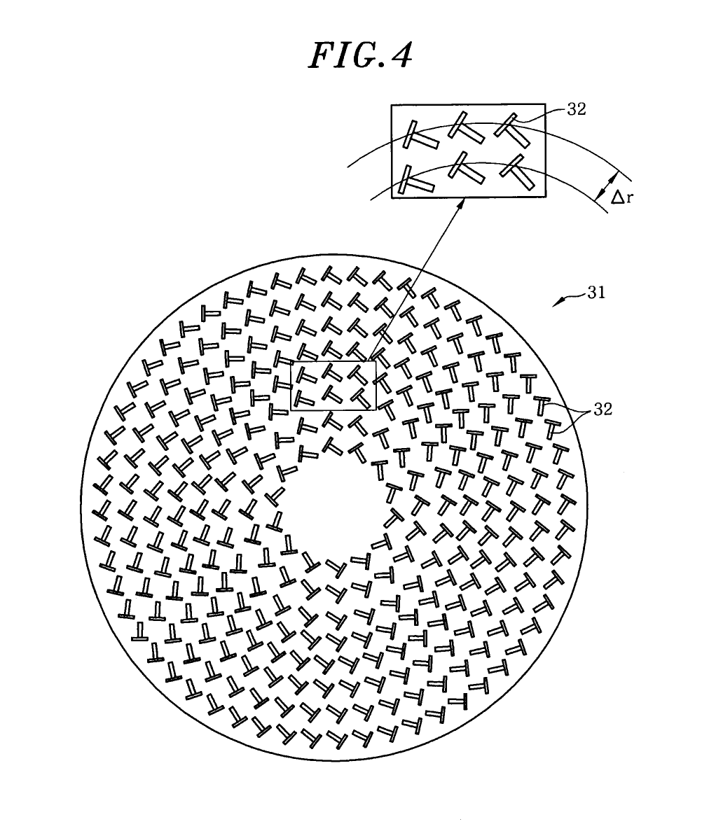

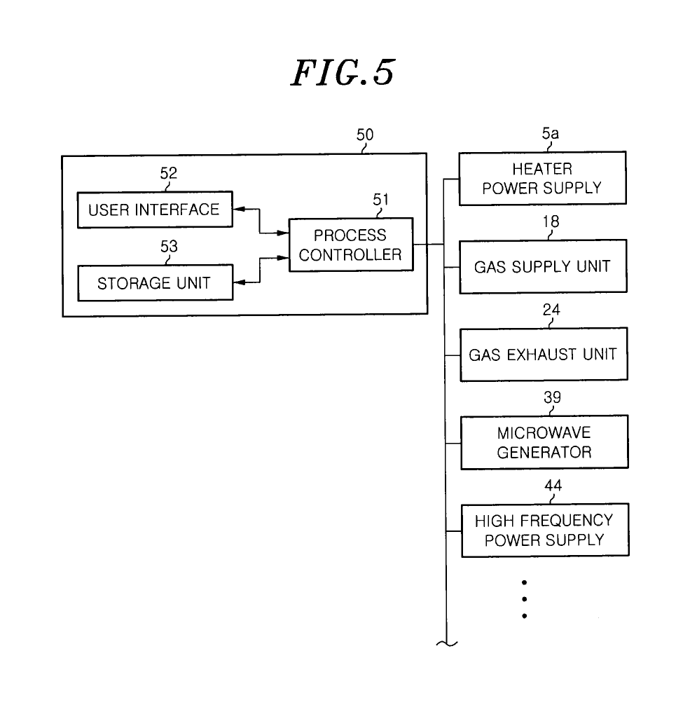

Each component of the plasma processing apparatus 100 is connected to and controlled by a control unit 50. The control unit 50 is typically a computer. For example, as shown in FIG. 5, the control unit 50 includes a process controller 51 having a CPU; and a user interface 52 and a storage unit 53 which are connected to the process controller 51. The process controller 51 serves to integratedly control, in the plasma processing apparatus 100, the respective components (e.g., the heater power supply 5a, the gas supply unit 18, the gas exhaust unit 24, the microwave generator 39, the high frequency power supply 44 and the like) which are associated with the processing conditions such as temperature, pressure, gas flow rate, microwave output, bias-application output of high frequency power, and the like.

The user interface 52 includes a keyboard through which a process operator performs, e.g., an input operation in accordance with commands in order to manage the plasma processing apparatus 100, a display for visually displaying an operational status of the plasma processing apparatus 100 and the like. Moreover, the storage unit 53 stores a recipe including process condition data or control programs (software) for performing various processes in the plasma processing apparatus 100 under the control of the process controller 51.

Further, if necessary, a certain recipe is retrieved from the storage unit 53 in accordance with instructions inputted through the user interface 52 and executed by the process controller 51. Accordingly, a desired process is performed in the processing chamber 1 of the plasma processing apparatus 100 under the control of the process controller 51. The recipe including process condition data or control programs may be stored in a computer-readable storage medium (e.g., CD-ROM, hard disk, flexible disk, flash memory, DVD, blue-ray disc and the like). Alternatively, the recipe may be transmitted from other devices through, e.g., a dedicated line.

In the plasma processing apparatus 100 having the above configuration, the plasma treatment can be performed at a temperature of about 600° C. or less, e.g., a low temperature between a room temperature (about 20° C.) and about 600° C., without causing damage to a base film formed on the wafer W or the like. Further, since the plasma processing apparatus 100 has an excellent plasma uniformity, in-plane uniformity of processing may be achieved even on a large-sized wafer W (target object to be processed).

Next, the plasma oxidation using the RLSA-type plasma processing apparatus 100 will be described. First, a gate valve 17 is opened, and a wafer W is loaded into the processing chamber 1 through the loading/unloading port 16. The wafer W is mounted on the mounting table 2 and then is heated to a predetermined temperature by the heater 5 installed in the mounting table 2.

Next, an inactive gas and an ozone-containing gas containing O₃ of high concentration are respectively introduced into the processing chamber 1 at predetermined flow rates from the inactive gas supply source 19a and the ozone-containing gas supply source 19b of the gas supply unit 18 through the gas supply lines (the gas lines 20b and 20ab) that have been subjected to the passivation process while the processing chamber 1 is vacuum-evacuated by the vacuum pump of the gas exhaust unit 24. In this manner, the internal pressure of the processing chamber 1 is adjusted to a predetermined level.

Next, the microwave of a predetermined frequency, e.g., 2.45 GHz, generated from the microwave generator 39 is transmitted to the waveguide 37 via the matching circuit 38. The microwave transmitted to the waveguide 37 passes through the rectangular waveguide 37b and the coaxial waveguide 37a in that order, and is supplied to the planar antenna 31 through the internal conductor 41. In other words, the microwave propagates in the TE mode in the rectangular waveguide 37b, and the TE mode of the microwave is converted into the TEM mode by the mode transducer 40. The TEM mode microwave propagates in the coaxial waveguide 37a toward the planar antenna 31. Then, the microwave is radiated to the space above the wafer W in the processing chamber 1, through the transmitting plate 28 serving as a dielectric member, from the slot-shaped microwave radiation holes 32 that are formed to extend through the planar antenna 31. At this time, the output power of the microwave may be selected in a range from, e.g., about 0.2555 W/cm² to 2.55 W/cm², in the case of processing the wafer W having a diameter of, e.g., about 200 mm or above.

An electromagnetic field is generated in the processing chamber 1 by the microwave radiated into the processing chamber 1 from the planar antenna 31 through the transmitting plate 28, so that the inactive gas and the ozone-containing gas are converted into a plasma. At this time, the microwave is radiated through the microwave radiation holes 32 of the planar antenna 31, thereby generating a plasma having a high density in a range from about 1×10¹° /cm³ to 5×10¹²/cm³ and a low electron temperature of about 1.2 eV or less in the vicinity of the wafer W. By using the plasma thus generated, it is possible to reduce damage to the wafer W caused by ions or the like in the plasma. As a result, the plasma oxidation is performed on silicon (single crystalline silicon, polycrystalline silicon or amorphous silicon) formed on the surface of the wafer W by action of active species, e.g., radicals or ions, in the plasma so that a good-quality silicon oxide film is formed.

While the plasma oxidation is being performed, a high frequency power having a predetermined frequency and power can be supplied from the high frequency power supply 44 to the mounting table 2, if necessary. With the high frequency power supplied from the high frequency power supply 44, a bias voltage (high frequency bias) is applied to the wafer W. As a result, the anisotropy of the plasma oxidation process is accelerated while a low electron temperature is maintained. In other words, by applying the bias voltage to the wafer W, an electromagnetic field is generated near the wafer W, so that ions in the plasma are attracted to the wafer W. As a consequence, the oxidation rate is increased.

(Plasma Oxidation Process Conditions)

Hereinafter, desired conditions for the plasma oxidation process performed in the plasma processing apparatus 100 will be described. It is preferable to use an ozone-containing gas as for a processing gas and Ar gas as for an inactive gas. A high concentration ozone-containing gas having a volume ratio of O₃ to a total volume of O₂ and O₃ contained in the ozone-containing gas, ranging 50% or more, or preferably from a 60% to 80%, may be employed as for the ozone-containing gas.

In the plasma of the gas containing high concentration ozone, the production amount of O(¹D₂) radicals is increased, so that a good-quality silicon oxide film can be obtained at a high oxidation rate. On the other hand, when the volume ratio of O₃ to the total volume O₂ and O₃ in the ozone-containing gas is lower than about 50%, the production amount of O(¹D₂) radicals is substantially the same as that of O(¹D₂) radicals in the plasma of the conventional O₂ gas and, thus, the processing rate is not changed. Accordingly, it is difficult to obtain a good-quality silicon oxide film at a high oxidation rate.

The flow rate ratio (e.g., volume ratio) of the ozone-containing gas (total volume of O₂ and O₃) contained in the all the processing gases may range preferably from about 0.001% to 5%, more preferably from about 0.01% to 2%, and most preferably from about 0.1% to 1% in terms of obtaining a sufficient oxidation rate. By using the plasma of the ozone-containing gas containing high concentration ozone in the above ranges of the flow rate ratio, it is possible to obtain a good-quality silicon oxide film at a high oxidation rate with the increase in the amount of O(¹D₂) radicals.

Moreover, a processing pressure may be set within the range from about 1.3 Pa to 1333 Pa. The processing pressure is preferably set within the range from about 1.3 Pa to 133 Pa, more preferably within the range from about 1.3 Pa to 66.6 Pa, and most preferably within the range from 1.3 Pa to 26.6 Pa, in terms of obtaining a high oxidation rate while maintaining a good film quality.

The following description relates to a desired combination between a flow rate ratio of an ozone-containing gas in the processing gas and a processing pressure. In order to form a good-quality silicon oxide film at a high oxidation rate, it is preferable to set the flow rate ratio (volume ratio) of the ozone-containing gas in the processing gas to be within the range from about 0.01% to 2% and the processing pressure within the range from about 1.3 Pa to 26.6 Pa.

In the present embodiment, during the plasma oxidation, it is preferable to supply a high frequency power having a predetermined frequency and power from the high frequency power supply 44 to the mounting table 2 and apply a high frequency bias to the wafer W. The frequency of the high frequency power supplied from the high frequency power supply 44 preferably ranges from, e.g., about 100 kHz to 60 MHz, and more preferably ranges from about 400 kHz to 13.5 MHz. As a power density per unit area of the wafer W, the high frequency power is supplied preferably in the range of, e.g., about 0.2 W/cm² and above, and more preferably in the range from about 0.2 W/cm² to 1.3 W/cm². Moreover, the high frequency power preferably ranges from about 200 W to 2000 W, and more preferably ranges from about 300 W to 1200 W.

The high frequency power supplied to the mounting table 2 has a function of attracting ion species in the plasma toward the wafer W while maintaining the low electron temperature in the plasma. By supplying the high frequency power, ion-assisted reaction becomes strong so that the silicon oxidation rate can be improved. In the present embodiment, the plasma has a low electron temperature. Accordingly, even if a high frequency bias is applied to the wafer W, the silicon oxide film is not damaged by ions or the like in the plasma, and a good-quality silicon oxide film can be formed at a high oxidation rate in a short period of time.

Further, in the plasma oxidation, a power density of the microwave preferably ranges from about 0.255 W/cm² to 2.55 W/cm² in terms of suppressing plasma damage. In the present invention, the power density of the microwave indicates a microwave power per unit area of 1 cm² of the wafer W. For example, when a wafer W having a diameter of about 300 mm or above is processed, it is preferable to set a microwave power within the range from about 500 W to 5000 W, and more preferably within the range from about 1000 W to 4000 W.

The processing temperature of the wafer W, i.e., the heating temperature of the wafer W, is preferably set within the range from, e.g., about 20° C. (a room temperature) to 600° C., more preferably within the range from about 200° C. to 500° C., and most preferably within the range from about 400° C. to 500° C. A good-quality silicon oxide film can be formed in a short period of time at a low temperature of about 600° C. or less and a high oxidation rate.

During the plasma generation, dissociation of O₃ occurs as in the following formulae F1 to F3.

O₃+e→O₂+O(¹D₂) F1

O₂+e→20(³P₂)+e→O(¹D₂)+O(³P₂)+e F2

O₂+e→O₂⁺+2e F3

“e” indicates an electron in the following formulae F1 to F3.

In the formulae F1 to F3, the formulae F2 and F3 correspond to the dissociation of O₂. Hence, when only O₂ gas is used as a processing gas, the dissociation reactions described in the formulae F2 and F3 are performed. On the other hand, when an ozone-containing gas (containing O₃ and O₂) is used as the processing gas, the dissociation reactions described in the formulae F1 to F3 are performed. Therefore, the possibility in which O(¹D₂) radicals are generated is higher when the ozone-containing gas is dissociated than when the oxygen gas is dissociated. Further, even if a large amount of electrons (e) are produced during the plasma generation process, the produced electrons are consumed by the dissociation reactions described in the formula F1. Hence, the dissociation of the oxygen gas in the formulae F2 and F3 is relatively decreased.

Accordingly, by using an ozone-containing gas, it is possible to produce a large amount of O(¹D₂) radicals compared to an oxygen gas. In other words, in the case of the plasma using an ozone-containing gas, it is considered that the balance between ions and radicals is changed so that a plasma mainly formed of radicals can be generated, compared to the case of the plasma using an oxygen gas. As a result, a formed silicon oxide film has a good quality.

In the present embodiment, a plasma having a large amount of O(¹D₂) radicals can be generated by using an ozone-containing gas having O₃ of high concentration. As a result, an oxidation reaction is performed mainly by O(¹D₂) radicals, so that a silicon oxide film having a good quality same as that of a thermal oxide film can be formed at a relatively low processing temperature of about 600° C. or less. Particularly, by setting a power density of a microwave to be within the range from about 0.255 W/cm² to 2.55 W/cm², it is possible to suppress the plasma damage, thereby further improving the film quality of the silicon oxide film.

By using an ozone-containing gas containing O₃ of high concentration, the amount of O(¹D₂) radicals is increased even when a flow rate ratio (volume ratio) of an ozone-containing gas (total volume ratio of O₂ and O₃) included in all the processing gas is set to be relatively low, for example, in a range from about 0.001% to 5%. Accordingly, a good-quality silicon oxide film can be obtained at a high speed. In the RLSA type plasma processing apparatus 100, ion-assisted radical oxidation is performed. Further, it is considered that the oxidation by O(¹D₂) radicals is facilitated by O₂⁺ ions, and this contributes to the increase in an oxidation rate.

Thus, at a processing pressure of about 133 Pa or less (preferably about 66.6 Pa or less and more preferably about 26.6 Pa or less) in which the amount of O₂⁺ ions is increased, a plasma of an ozone-containing gas containing O₃ of high concentration is generated in such a way as to have O(¹D₂) radicals and O₂⁺ ions with a good balance. Therefore, the oxidation in which O(¹D₂) radicals become dominant by assist of O₂⁺ions is effectively carried out, which leads to the increase in an oxidation rate. Moreover, during the plasma oxidation, by supplying a high frequency power of, e.g., about 0.2 W/cm² or above per unit area of the wafer W from the high frequency power supply 44 to the mounting table 2 and applying a high frequency bias to the wafer W, it is possible to enhance the ion-assisted reaction and further improve a silicon oxidation rate.

The above-described conditions are stored as recipes in the storage unit 53 of the control unit 50. Further, the process controller 51 reads out the recipes and transmits control signals to the respective components of the plasma processing apparatus 100, e.g., the gas supply unit 18, the gas exhaust unit 24, the microwave generator 39, the heater power supply 5a, the high frequency power supply 44 and the like. Accordingly, the plasma oxidation is realized under desired conditions.

The silicon oxide film formed by the plasma oxidation method in accordance the embodiment of the present invention has a good quality same as that of a thermal oxidation film, and thus can be preferably used as, e.g., a gate insulating film of a transistor or the like.

Hereinafter, results of tests that have examined the effects of the present invention will be described.

### Test 1

An oxidation process was performed under the following conditions, and a silicon oxide film was formed on a surface of a silicon substrate (wafer W). A condition 1 corresponds to an O₃ plasma oxidation in accordance with the method of the present invention; a condition 2 corresponds to an O₂ plasma oxidation as a comparative example; and a condition 3 corresponds to a thermal oxidation as a comparative example. Further, ozone concentration [percentage of O₃/(O₂+O₃)] in an employed ozone-containing gas was about 80 vol %.

(Condition 1; O₃ Plasma Oxidation)

Ar flow rate: 163.3 mL/min (sccm)

Ozone-containing gas flow rate: 1.7 mL/min (sccm)

Processing pressure: 133 Pa

Microwave power: 4000 W (power density 2.05 W/cm²)

Processing temperature (temperature of wafer W): 400° C.

Processing time (formed film thickness): 3 min (3.4 nm), 6 min (4.6 nm), 10 min (6.0 nm)

(Condition 2; O₂ Plasma Oxidation)

Ar flow rate: 163.3 mL/min (sccm)

O₂ flow rate: 1.7 mL/min (sccm)

Processing pressure: 133 Pa

Microwave power: 4000 W (power density 2.05 W/cm²)

Processing temperature (temperature of wafer W): 400° C.

Processing time (formed film thickness): 3 min (4.6 nm), 6 min (5.6 nm), 10 min (6.8 nm)

(Condition 3; Thermal Oxidation)

O₂ flow rate: 450 mL/min (sccm)

H₂ flow rate: 450 mL/min (sccm)

Processing pressure: 700 Pa

Processing temperature (temperature of wafer W): 950° C.

Processing time (formed film thickness): 26 min (5.2 nm)

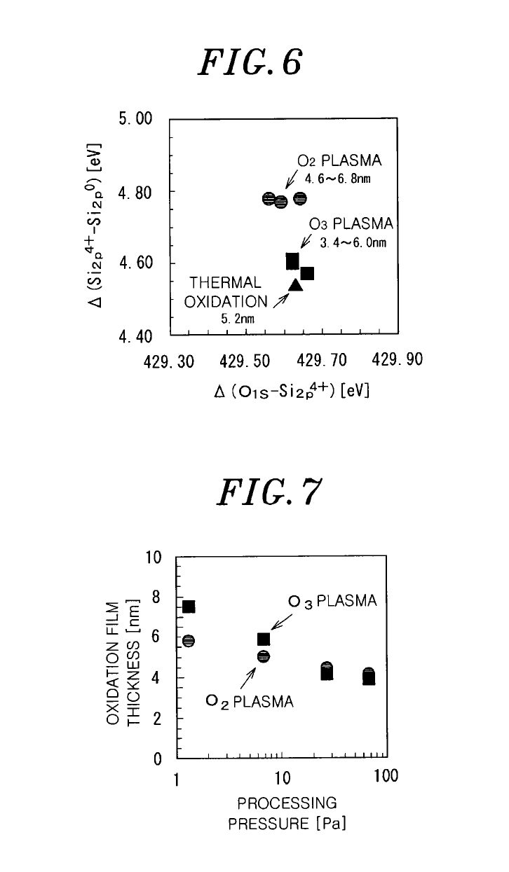

A silicon oxide film formed by the oxidation process performed under the conditions 1 to 3 was measured by XPS (X-ray photoelectron spectroscopy) analysis. In FIG. 6, a vertical axis indicates a difference (Si₂ₚ⁴⁺—Si₂ₚ⁰) between a binding energy of a silicon oxide film (Si₄⁴⁺) and a binding energy of a silicon substrate (Si₂ₚ⁰ ) which can be obtained from an XPS spectrum, and a horizontal axis indicates a difference (O₁₅−Si₂ₚ⁴⁺) between a binding energy (O₁₅) of oxygen and a binding energy of each silicon oxide film (Si₂ₚ⁴⁺). As can be seen from FIG. 6, the silicon oxide films have substantially the same value (O₁₅−Si₂ₚ⁴⁺) in the horizontal axis. This represents that Si—O binding monitored by the XPS spectrum has not been changed.

Meanwhile, the O₃ plasma oxidation of the condition 1 and the thermal oxidation of the condition 3 have the same value in the vertical axis (Si₂ₚ⁴⁺−Si₂ₚ⁰), and the O₂ plasma oxidation of the condition 2 has a higher value in the vertical axis compared to the conditions 1 and 3. A higher value in the vertical axis indicates occurrence of charge capture caused by X-ray irradiation in a silicon oxide film during the XPS measurement, which leads to a higher degree of deterioration by the X-ray irradiation. Therefore, the film quality obtained in the O₃ plasma oxidation of the condition 1 improved compared to that obtained in the O₂ plasma oxidation of the condition 2 and was substantially the same as that of the thermal oxide film. This shows that, by employing as the processing gas a high concentration ozone-containing gas having a volume ratio of O₃, ranging 50% or more, to a total volume of O₂ and O₃ , it is checked that a silicon oxide film having a same film quality as that obtained by a thermal oxidation process performed at about 950° C. can be formed even by a treatment performed at a low processing temperature of about 400° C.

### Test 2

An oxidation process was performed under the following conditions, and a silicon oxide film was formed on a surface of a silicon substrate (wafer W). A condition 3 corresponds to an O₃ plasma oxidation in accordance with the method of the present invention, and a condition 4 corresponds to an O₂ plasma oxidation as a comparative example. Moreover, ozone concentration [percentage of O₃/(O₂+O₃)] in an employed ozone-containing gas ranged from about 60 vol % to 80 vol %.

(Condition 3; O₃ Plasma Oxidation)

Ar flow rate: 163.3 mL/min (sccm)

Ozone containing gas flow rate: 1.7 mL/min (sccm)

Processing pressure: 1.3 Pa, 6.7 Pa, 26.6 Pa, 66.6 Pa

Microwave power: 4000 W (power density 2.05 W/cm²)

Processing temperature (temperature of wafer W): 400° C.

Processing time: 3 min

(Condition 4; O₂ Plasma Oxidation)

Ar flow rate: 163.3 mL/min (sccm)

O₂ flow rate: 1.7 mL/min (sccm)

Processing pressure: 1.3 Pa, 6.7 Pa, 26.6 Pa, 66.6 Pa

Microwave power: 4000 W (power density 2.05 W/cm²)

Processing temperature (temperature of wafer W): 400° C.

Processing time: 3 min

FIG. 7 shows a processing pressure dependency of a film thickness of a silicon oxide film formed under the above condition. In FIG. 7, a vertical axis indicates a film thickness (optical film thickness at a refractive index of about 1.462; this is true hereinafter) of a silicon oxide film, and a horizontal axis indicates a processing pressure. This shows that the oxidation film thickness obtained in the O₃ plasma oxidation of the condition 3 and that obtained in the O₂ plasma oxidation of the condition 4 are substantially the same at a processing pressure of about 26.6 Pa. However, at a lower processing pressure, the oxidation film thickness obtained in the O₃ plasma oxidation of the condition 3 is higher than that obtained in the O₂ plasma oxidation of the condition 4, which indicates a higher oxidation rate.

This result can be explained by the balance between O₂⁺ ions and O(¹D₂) radicals which contribute to the formation of the silicon oxide film. As described in the dissociation reactions of the formulae F1 to F3, in the O₃ plasma oxidation, it is thought that the number of O(¹D₂) radicals is considerably larger than that in the O₂ plasma oxidation and the number of O₂⁺ ions is smaller than that in the O₂ plasma oxidation. In the RLSA type plasma processing apparatus 100, ion-assisted radical oxidation was performed. It is considered that the oxidation by O(¹D₂) radicals is facilitated by O₂⁺ ions, and this contributes to the increase in an oxidation rate.

Since a higher energy is required for the generation of O₂⁺ ions than for the generation of O(¹D₂) radicals, O₂⁺ ions are not easily generated at a higher pressure at which an electron temperature is decreased. However, O₂⁺ ions are easily generated at a lower pressure at which an electron temperature is higher (the terms “lower pressure” and “higher pressure” are relative expressions: the lower pressure indicates a pressure of about 133 Pa or less, and the higher pressure indicates a pressure that is higher than about 133 Pa).

In the case of the plasma oxidation of the condition 3, although a dominant-radical oxidation having a large amount of O(¹D₂) radicals was performed, the oxidation rate was decreased at a high pressure at which the number of O₂⁺ ions that facilitated oxidation was small. However, at a low pressure at which the number of O₂⁺ ions was large, the number of O(¹D₂) radicals and the number of O₂⁺ ions were balanced. Hence, the oxidation in which O(¹D₂) radicals became dominant by assist of O₂⁺ ions effectively occurred, which led to the increase in an oxidation rate.

On the other hand, in the O₂ plasma oxidation of the condition 4, the number of O(¹D₂) radicals became smaller than that of O₂⁺ ions by dissociation described in the formulae F1 to F3, so that the oxidation rate was rate-controlled by O(¹D₂) radicals. This is considered as the reason that an oxidation rate was not considerably increased at a low pressure. In the plasma oxidation method of the present invention, the processing pressure is not particularly limited. However, the test result shows that, in the O₃ plasma oxidation in which a large number of O(¹D₂) radicals is produced, it is preferable to set the processing pressure to be lower than or equal to about 133 Pa in view of the increase in an oxidation rate, more preferably within the range from about 1.3 Pa to 66.6 Pa, and most preferably within the range from about 1.3 Pa to 26.6 Pa.

### Test 3

An oxidation process was performed under the following conditions, and a silicon oxide film was formed on a surface of a silicon substrate (wafer W). A condition 5 corresponds to an O₃ plasma oxidation in accordance with the method of the present invention, and a condition 6 corresponds to an O₂ plasma oxidation as a comparative example. Moreover, ozone concentration [percentage of O₃/(O₂+O₃)] in an employed ozone-containing gas ranged from about 60 vol % to 80 vol %.

(Condition 5; O₃ Plasma Oxidation)

Volume flow rate ratio [percentage of ozone containing gas flow rate/(ozone containing gas flow rate+Ar flow rate)]: 0.001%, 0.01%, 0.1%

Processing pressure: 133 Pa

Microwave power: 4000 W (power density 2.05 W/cm²)

Processing temperature (temperature of wafer W): 400° C.

Processing time: 3 min

(Condition 6; O₂ Plasma Oxidation)

Volume flow rate ratio [ratio of O₂ flow rate/(O₂ flow rate+Ar flow rate)]: 0.001%, 0.01%, 0.1%

Processing pressure: 133 Pa

Microwave power: 4000 W (power density 2.05 W/cm²)

Processing temperature (temperature of wafer W): 400° C.

Processing time: 3 min

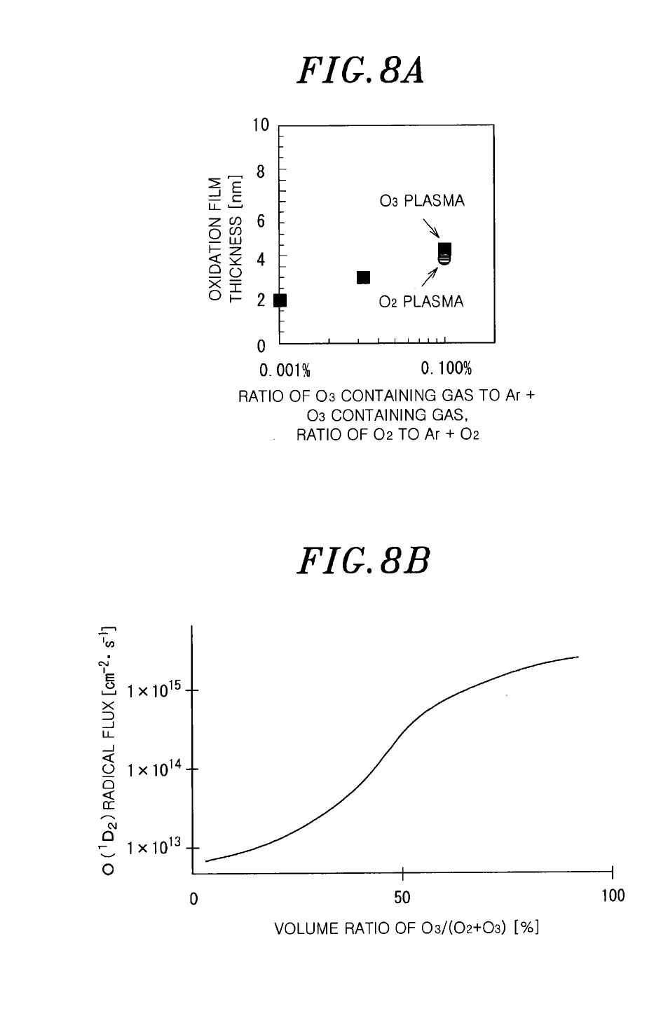

FIG. 8A shows a relationship between a volume flow rate ratio (horizontal axis) of an ozone-containing gas or an oxygen gas to all the processing gases and a film thickness (vertical axis) of a silicon oxide film. In the O₃ plasma oxidation of the condition 5, an oxidation film thickness was larger even at a low volume flow rate ratio of about 0.1%, compared to the O₂ plasma oxidation of the condition 6, thereby obtaining a high oxidation rate at a low concentration. As described in the dissociation reaction of the formulae F1 to F3, the O₃ plasma oxidation is the radical-dominant oxidation having a larger number of O(¹D₂) radicals than the O₂ plasma oxidation.

FIG. 8B shows a relationship between a volume ratio of O₃/(O₂+O₃) and an O(¹D₂) radical flux. As can be seen from FIG. 8B, when the volume ratio of O₃/(O₂+O₃) was about 50% or above, the O(¹D₂) radical flux was increased to a sufficient level. Hence, by using an ozone-containing gas having a volume ratio of O₃ to a total volume of O₂ and O₃, ranging 50% or more, a sufficient oxidation rate higher than that obtained in the O₂ plasma oxidation was able to be obtained as shown in FIG. 8A even if a volume flow rate ratio of the ozone-containing gas in the processing gas was about 0.1% or below.

### Test 4

Next, the difference between the case of supplying a high frequency power to the mounting table 2 by using the plasma processing apparatus 100 and the case of supplying no high frequency power was examined. An oxidation process was performed under the following conditions, and a silicon oxide film was formed on a surface of a silicon substrate (wafer W). A condition 7 corresponds to an O₃ plasma oxidation in accordance with the method of the present invention, and a condition 8 corresponds to an O₂ plasma oxidation as a comparative example. Moreover, ozone concentration [percentage of O₃/(O₂+O₃)] in an employed ozone-containing gas ranged from about 60 vol % to 80 vol %.

(Condition 7; O₃ Plasma Oxidation)

Ar flow rate: 163.3 mL/min(sccm)

Ozone containing gas flow rate: 1.7 mL/min(sccm)

Processing pressure: 133 Pa

Frequency of high frequency bias power: 13.56 MHz

High frequency bias power: 0 W (no application), 150 W, 300 W, 600 W, 900 W

High frequency bias power density: 0 W/cm², 0.21 W/cm², 0.42 W/cm², 0.85 W/cm², 1.27 W/cm²

Microwave power: 4000 W(power density 2.05 W/cm²)

Processing temperature (temperature of wafer W): 400° C.

Processing time: 3 min

(Condition 8; O₂ Plasma Oxidation)

Ar flow rate: 163.3 mL/min (sccm)

O₂ flow rate: 1.7 mL/min (sccm)

Processing pressure: 133 Pa

Frequency of a high frequency power: 13.56 MHz

High frequency bias power: 0 W (no application), 150 W, 300 W, 600 W, 900 W

High frequency bias power density: 0 W/cm², 0.21 W/cm², 0.42 W/cm², 0.85 W/cm², 1.27 W/cm²

Microwave power: 4000 W (power density 2.05 W/cm²)

Processing temperature (temperature of wafer W): 400° C.

Processing time: 3 min

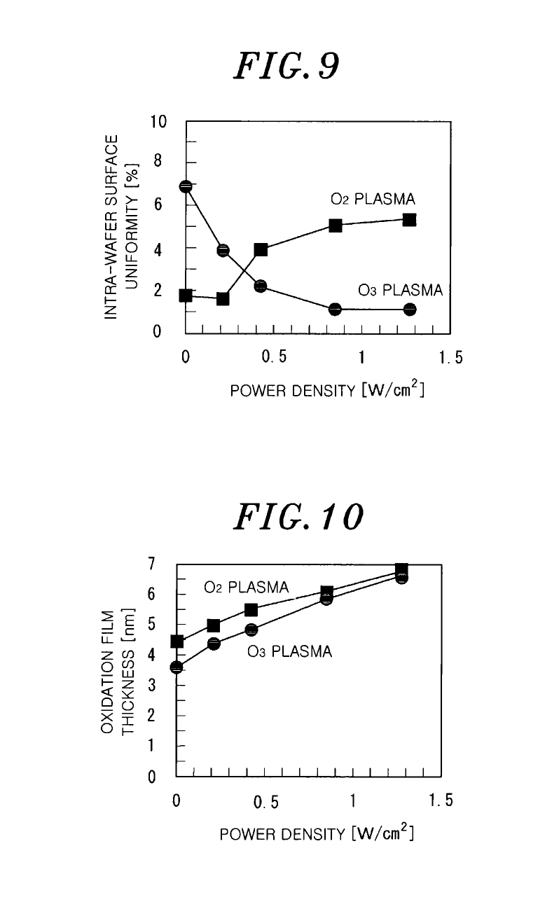

FIG. 9 shows a relationship between a power density of a high frequency power supplied to the mounting table 2 (horizontal axis) and an intra-wafer surface uniformity of a silicon oxide film (vertical axis). FIG. 10 shows a relationship between a power density of a high frequency power (horizontal axis) and an oxidation film thickness (vertical axis). The intra-wafer surface uniformity shown in FIG. 9 was calculated as a percentage (×100%) of (maximum film thickness in the intra-wafer surface−minimum film thickness of the intra-wafer surface)/(average film thickness of the intra-wafer surface×2). As shown in FIG. 9, in the O₃ plasma oxidation of the condition 7, as the power density of the high frequency bias power was increased, the intra-wafer surface uniformity was improved, which was the opposite tendency to the case of the O₂ plasma oxidation of the condition 8.

Further, as shown in FIG. 10, the oxidation film thickness obtained in the O₃ plasma oxidation of the condition 7 was increased as the power density of the high frequency bias was increased. At the power density of the high frequency bias power of about 0.85 W/cm², the oxidation film thickness was improved until the oxidation rate substantially the same as that of the O2 plasma oxidation of the condition 8 was obtained. This result shows that, by supplying a high frequency power to the mounting table 2, ions or radicals are attracted to the wafer W and, thus, it is possible to increase an oxidation rate in the O₃ plasma oxidation and improve the oxidation film thickness uniformity of the intra-wafer surface. Moreover, when the high frequency power density ranges from at least about 0.2 W/cm² to 1.3 W/cm², the intra-wafer surface uniformity and the oxidation rate are improved as the power density is increased.

While the embodiments of the present invention have been described, the present invention can be variously modified without being limited to the above embodiments. For example, in the above embodiments, the RLSA-type plasma processing apparatus has been described as an apparatus for performing the silicon oxide film forming method in accordance the embodiment of the present invention. However, another type plasma processing apparatus such as an inductively coupled plasma (ICP) type, a magnetron type, an electron cyclotron resonance (ECR) type, a surface wave type or the like may be employed. Further, a target substrate to be processed is not limited to a semiconductor substrate, and may be another substrate, e.g., a glass substrate, a ceramic substrate or the like.

This application claims priority to Japanese Patent Application No. 2010-64080 filed on Mar. 19, 2010, the entire contents of which are incorporated herein by reference.

What is claimed is:

1. A silicon oxide film forming method comprising:
forming a silicon oxide film by allowing a plasma of a processing gas to react on a silicon exposed on a surface of a target object to be processed in a processing chamber of a plasma processing apparatus, the processing gas including an ozone-containing gas having a volume ratio of O₃ to a total volume of O₂ and O₃, ranging 50% or more.

2. The silicon oxide film forming method of claim 1, wherein a pressure in the processing chamber ranges from about 1.3 Pa to about 1333 Pa.

3. The silicon oxide film forming method of claim 1, wherein an oxidation process is performed while a high frequency power of a magnitude ranging from about 0.2 W/cm² to 1.3 W/cm² per an area of the target object is supplied to a mounting table for mounting thereon the target object in the processing chamber.

4. The silicon oxide film forming method of claim 1, wherein a processing temperature corresponds to a temperature of the target object and ranges from about 20° C. to 600° C.

5. The silicon oxide film forming method of claim 1, wherein the plasma corresponds to a microwave-excited plasma formed by using the processing gas and a microwave introduced into the processing chamber by a planar antenna having a plurality of slots.

6. The silicon oxide film forming method of claim 5, wherein a power density of the microwave ranges from about 0.255 W/cm² to 2.55 W/cm² per unit area of the target object.

7. A plasma oxidation apparatus comprising:
a processing chamber having an opening formed at an upper portion thereof, for processing a target object to be processed by using a plasma;
a dielectric member for covering the opening of the processing chamber,
an antenna provided outside the dielectric member, for introducing an electromagnetic wave into the processing chamber;
a gas inlet for introducing a processing gas including an ozone-containing gas into the processing chamber;
a gas exhaust port for vacuum-evacuating the inside of the processing chamber;
a mounting table for mounting the target object thereon in the processing chamber; and
a control unit configured to form a silicon oxide film by supplying into the processing chamber a processing gas containing an ozone-containing gas having a volume ratio of O₃ to a total volume of O₂ and O₃, raging 50% or more, while introducing an electromagnetic wave into the processing chamber by the antenna, and generating a plasma of the processing gas and allowing the plasma to react on a silicon exposed on the surface of the target object.

8. The plasma oxidation apparatus of claim 7, further comprising a gas supply line, of which inner surface is subjected to a passivation process, for supplying the ozone-containing gas into the processing chamber, the gas supply line having one end connected to the gas inlet and the other end connected to an ozone-containing gas supply source.

9. The plasma oxidation apparatus of claim 8, wherein the gas inlet includes a gas channel having a gas opening through which a gas is injected into a processing space in the processing chamber, and a passivation process is performed on a part or an entire part of the gas channel and an inner wall surface of the processing chamber around the gas opening.

10. The plasma oxidation apparatus of claim 7, further comprising a high frequency power supply for supplying a high frequency power ranging from about 0.2 W/cm² to 1.3 W/cm² per unit area of the target object to the mounting table.
